(19) United States
(12) Patent Application Publication
(10) Pub. No.: US 2009/0002002 A1
(43) Pub. Date: Jan. 1, 2009

(54) Electrical Testing System

(76) Inventor: Wen-Bi Hsu, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 11/772,220

(22) Filed: Jun. 30, 2007

(51) Int. Cl. G01R 31/02

(52) U.S. Cl. 324/754

(57) ABSTRACT

Electrical testing system which is mainly used for testing double-sided printed board (DSB) (having terminals which are electrically connected with each other are separately provided on the two sides, respectively) is provided. The system includes a test board which is electrically contacted with the PCB, a test fixture which supports the test board and the PCB, testing probes which output an electrical signal, and a sensor which receives the electrical signal through the PCB and the test board. When the PCB is mounted on the test board, the electrical signal outputted from the testing probes sequentially is transmitted to the test board through the PCB, and based upon whether the sensor receives the electrical signal to thereby determine whether the terminals on the PCB corresponding to the testing probes are under the open circuit or the short circuit condition.

### BACKGROUND OF THE INVENTION

1. Field of the Invention

The present invention relates generally to an electrical testing system, and in particular to an electrical testing system used for testing the double-sided bare board.

2. The Prior Arts

Electronic assembly testing typically includes of two types: a bare board test and a loaded board test. Herein, the bare board test is performed after the completion of the fabrication of the PCB, which mainly includes the testing of a short circuit, an open circuit or a shorted circuit, and the conductivity of a net list. There are also many other inspection and testing methods during the fabrication process. The loaded board test is more complex than the bare board test, and is to be performed after the electronic assembly is completed.

The testing performed during the electronic assembly includes the following: manufacturing defect analysis (MDA), in-circuit test (ICT), and function test (allowing the products to perform under application environment), and a combination of the above three tests. In recent years, assembly testing also includes the automated-optical inspection (AOI) and the automated x-ray inspection (AXI) tests. They can provide the static images of the PCB and the separated layer images of the x-rayed PCBs at different planes for determining the welding flaws and solder joint bridging defects.

The conventional tests are divided into five types, in which their main functions include the following: (1) the bare board test—which detects the defects of the open circuit or short circuit and the short circuit defect of the bare PCB; (2) production defect analysis—which detects the short circuit and the open circuit or the short circuit defect of the solder joint on the PCB containing the soldered components; (3) in-circuit test—which assesses the proper operation for each of the individual components; (4) function test—which affirms the proper operation of the function module of the PCB; (5) combination test—which is a combination of the in-circuit test and the function test.

During the electrical test of the single-sided printed board (SSB), based on the known circuit design, two terminals which are in theory connected with each other are selected from the PCB which is yet to be tested. One of the two terminals is used for outputting the electrical signal, and the other terminal is used for receiving the electrical signal. If the probes cannot receive the aforementioned electrical signal, the terminals are deemed to be under the open circuit or the short circuit.

However, in regards to the electrical test on the double-sided printed board (DSB), the method above cannot be performed satisfactorily. This is because, for the DSB, the terminals which are to be connected in theory are sometimes located on the two sides of the PCB, respectively; as a result, the original electrical test method used on the SSB cannot be reproduced on the DSB.

### SUMMARY OF THE INVENTION

A primary objective of the present invention is to provide an electrical testing system for performing test inspection on the DSB by disposing probes and sensors on the two sides of the PCB yet to be tested, respectively.

According to the objective, the solution of the present invention is to provide an electrical testing system to perform inspection on the DSB (as there are terminals which are electrically connected with each other on each of the two sides, respectively). The system includes a test board for forming electrical contact with the PCB, a test fixture for supporting the test board and the PCB, a plurality of testing probes for outputting the electrical signal, and a sensor for receiving the electrical signal through the PCB and the test board. When the PCB is mounted on the test board, the electrical signals are correspondingly outputted from the testing probes in sequence, and are transmitted to the PCB through the test board, and based upon whether the electrical signal is received by the sensor to thereby determine whether the terminals on the PCB which are corresponded to the testing probes are under the open circuit or short circuit condition.

### BRIEF DESCRIPTION OF THE DRAWINGS

The present invention will be apparent to those skilled in the art by reading the following detailed description of a preferred embodiment thereof, with reference to the attached drawings, in which:

FIGS. 1A to 1C are a plurality of plan views showing an electrical testing system in accordance with an embodiment of the present invention;

FIGS. 2A to 2B are a plurality of sectional views showing the electrical testing system in accordance with the preferred embodiment of the present invention.

### DETAILED DESCRIPTION OF THE PREFERRED EMBODIMENT

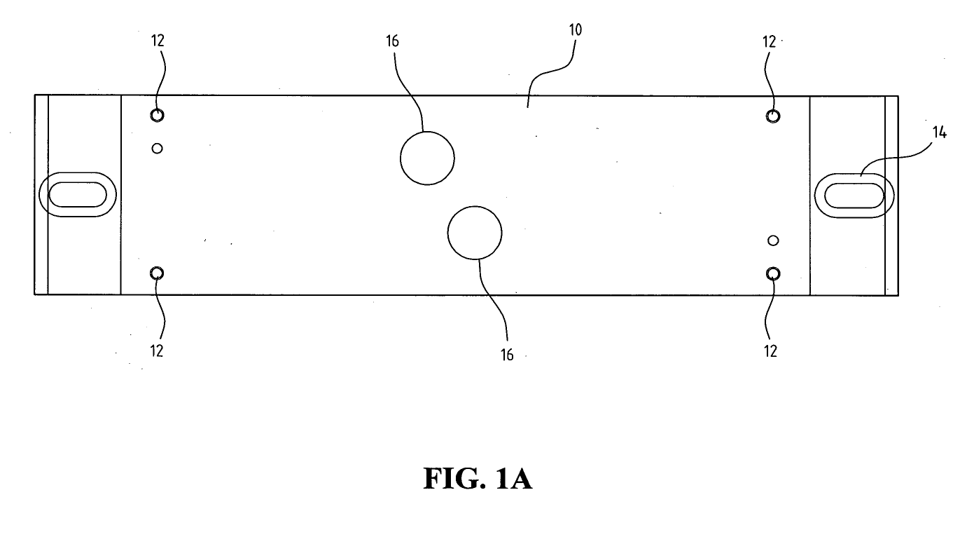

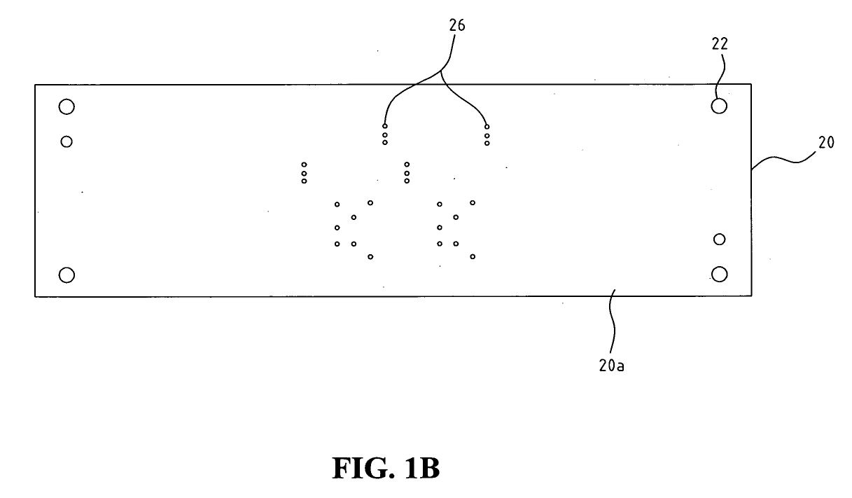

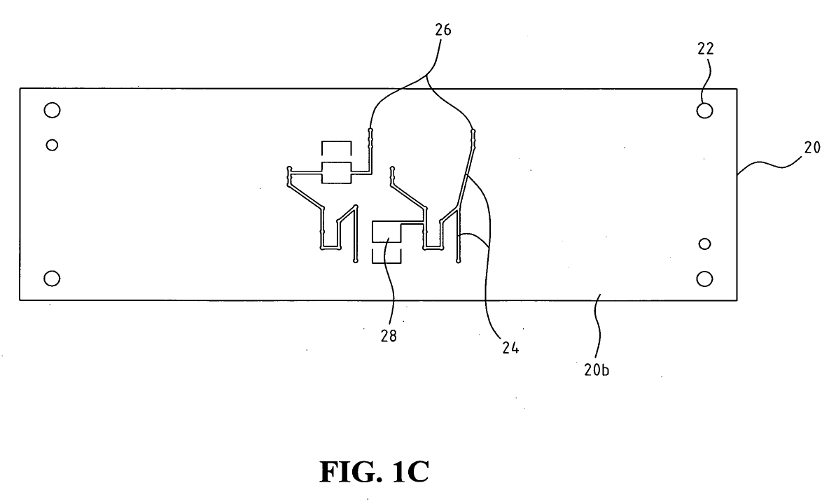

Referring to FIGS. 1A to 1C, FIGS. 1A to 1C are a plurality of plan views showing an electrical testing system in accordance with an embodiment of the present invention. The test fixture 10 used in the system is shown in FIG. 1A. A test board 20 used in the system is shown in FIG. 1B to FIG. 1C. FIG. 1B is the plan view showing a front side 20a of the test board 20, and FIG. 1C is the plan view showing a back side 20b of the test board 20.

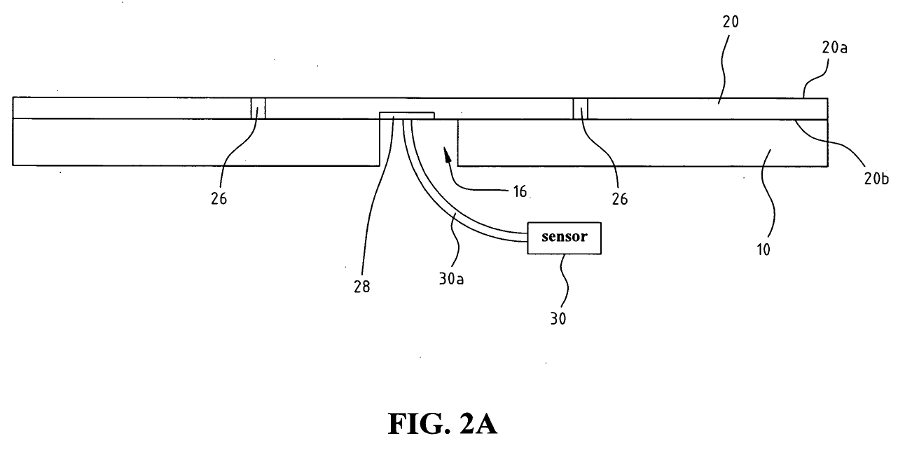

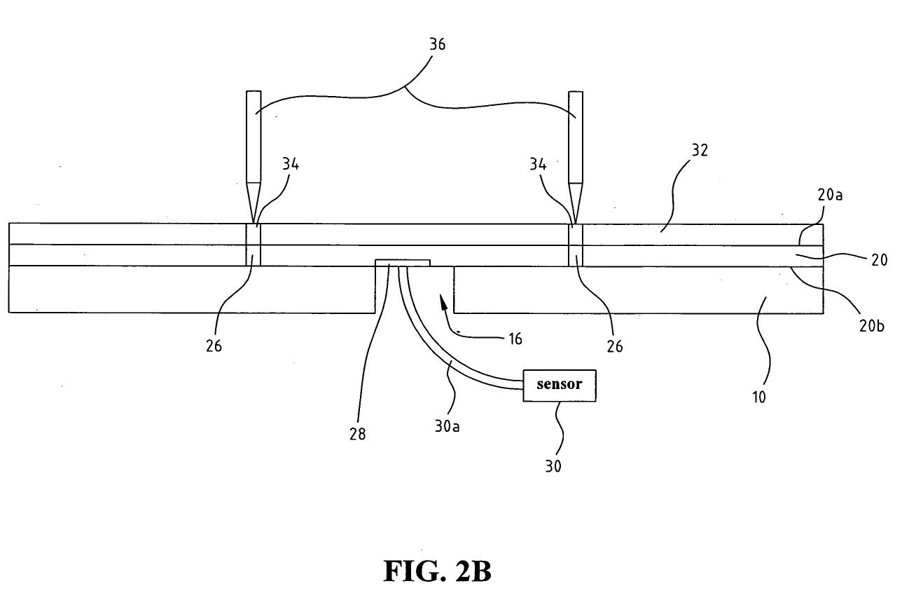

Referring to FIGS. 2A-2B, FIGS. 2A-2B are a plurality of sectional views showing the electrical testing system in accordance with a preferred embodiment of the present invention. The completed assembly of the test fixture 10 and the test board 20 for the electrical testing system is shown in FIG. 2A. An actual testing performed on a PCB 32 is shown in FIG. 2B.

The electrical testing system according to the preferred embodiment of the present invention includes a test board 20 which can be electrically contacted with the PCB 32 (as shown in FIG. 2B), a test fixture 10 which can support the test board 20 and the PCB 32, a plurality of testing probes 36 which output an electrical signal (as shown in FIGS. 2A-2B), and a sensor 30 which receives the electrical signal through the PCB 32 and the test board 20 (as shown in FIG. 2B).

In simpler terms, as shown in FIG. 2B, when the PCB 32 is disposed on the test board 20, the electrical signal which is outputted from the testing probes 36 (can be performed sequentially) is transmitted to the test board 20 via the PCB 32, and is indirectly transmitted to the sensor 30; and based upon whether the sensor 30 receives the electrical signal, it is to determine whether the terminals 34 on the PCB which are corresponding to the testing probes 36 are under the open circuit or short circuit condition. Each element will be further described below, and followed by the descriptions of the method of assembly for conducting testing.

The PCB 32 which is awaiting inspection testing may be a chip on film (COF), a tape automated bonding (TAB), or a flexible print circuit (FPC), and there are terminals 34 which are electrically connected with each other on the two sides of the PCB 32, respectively.

As shown in FIG. 2B, the electrical signal outputted sequentially from one of the testing probes 36 can be transmitted to a detection points 26 on the PCB 20 through a conductive trace line 30a, and is thereby indirectly transmitted to each of the terminals 34 on the PCB 20 which has already been assembled.

As shown in FIG. 1A, the test fixture 10 (comprised of insulating material) includes a via 16, and the size of the via 16 is big enough for the conductive trace line 30a to pass through to connect with the sensor 30.

As shown in FIGS. 1B-1C, the test board 20 is comprised of insulating material and has a plurality of detection points 26 which are made of metal; each of the detection points 26 may be opposite to the terminal 34 disposed on the back side of the PCB 32. The detection points 26 which are electrically connected with each other are disposed on the two sides of the test board 20. In further details, as viewed from the front side 20a of the test board 20, only the detection points 26 can be seen; meanwhile, as viewed from the back side 20b, the detection points 26 can be seen to connect with a connecting trace line 24, and a pad 28 may provide the solder junction for the conductive trace line 30a through the connecting trace line 24 connecting with the pad 28.

During the assembly, the test fixture 10 can be first mounted on the testing machine (not shown) by using a machine mounting element 14, as shown in FIG. 1A. Then, as shown in FIG. 2A, when the test board 20 is placed on the test fixture 10, the test fixture 10 and the test fixture 20 can be combined tightly together using the mounting holes 12, 22, as shown in FIGS. 1A-1C, and at the same time, the test board 20 can be mounted on the testing machine indirectly. In this case, the pad 28 on the test board 20 can be observed through the via 16 of the test fixture 10. Therefore, when the conductive trace line 30a is soldered on the pad 28, the electrical signal from the testing probes 36 is transmitted to the test board 20, and then to the PCB 32 indirectly.

As shown in FIG. 2B, because each of the detection points 26 is opposite to the corresponding terminal 34 on the back side of the PCB 32, the terminals 34 of the PCB 32 are to be connected with the corresponding detection points 26 on the test board 20, when the PCB 32 is placed on the test board 20. Meanwhile, when the testing probes 36 are connected with the terminals 34 on the front side of the PCB 32, the electrical signal which are sequentially outputted from the testing probes 36 in theory can be transmitted to the detection points 26, which thereby can be transmitted to the test board 20 through the PCB 32, and then indirectly to the sensor 30. Thus, based on the presence of the electrical signal or the lacking thereof as received by the sensor 30, it is possible to determine whether the terminals 34 on the PCB 32 which are corresponding to the testing probes 36 are under the open circuit or the short circuit condition.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. An electrical testing system for provide testing on double-sided printed circuit board (PCB), comprising:
a plurality of terminals connected with each other on the two sides of the PCB, respectively;
a test fixture, comprising of insulating material;
a test board, supported and mounted by the test fixture, and is made of insulating material, and comprising a plurality of detection points on the test board, and each of the detection points is disposed oppositely to the corresponding terminal on the back side of the PCB;
a plurality of testing probes, electrically contacting with the terminals on the front side on the PCB, and outputting an electrical signal to be transmitted to the detection points;
a sensor, electrically connected with the detection points through a conductive trace line, and is to receive the electrical signal from the detection points, wherein the PCB is mounted on the test board, the electrical signal are outputted from the testing probes sequentially and are transmitted to the test board through the PCB, and based on whether the sensor has received the electrical signal to thereby determine whether the terminals on the PCB corresponding to the testing probes are under the open circuit or short circuit condition.

2. The electrical testing system as claimed in claim 1, wherein the PCB is of a chip on film (COF), a tape automated bonding (TAB), or a flexible print circuit (FPC).

3. The electrical testing system as claimed in claim 1, wherein, the test fixture comprising a via, and the size of the via is big enough for the conductive trace line to pass through to connect with the sensor.

4. The electrical testing system as claimed in claim 1, wherein the detection points which are electrically connected with each other are disposed on the two sides of the test board, and on the side wherein contacting to the test fixture, the detection points are connected by a conductive trace line, and are connected with a pad by using the conductive trace line, and the pad is to provide the solder junction for the conductive trace line.

5. The electrical testing system as claimed in claim 1, wherein one of the testing probes is to output the electrical signal sequentially whereby transmitted to the test board through the PCB, and based on whether the sensor receives the electrical signal to thereby determine whether the terminals on the PCB corresponding to the testing probes are under the open circuit or the short circuit condition.
